(19) United States
(12) Patent Application Publication
(10) Pub. No.: US 2024/0258188 A1
(43) Pub. Date: Aug. 1, 2024

(54) SEMICONDUCTOR DEVICE

(71) Applicant: Mitsubishi Electric Corporation, Tokyo (JP)

(72) Inventors: Shoji SAITO, Tokyo (JP); Seiichiro INOKUCHI, Tokyo (JP); Taishi SASAKI, Tokyo (JP); Hiroya SANNAI, Tokyo (JP)

(73) Assignee: Mitsubishi Electric Corporation, Tokyo (JP)

(21) Appl. No.: 18/560,567

(22) PCT Filed: Aug. 18, 2021
(86) PCT No.: PCT/JP2021/030097

§ 371 Date: Nov. 13, 2023

(51) Int. Cl. H01L 23/31; H01L 23/00; H01L 23/29; H01L 23/498

(52) U.S. Cl. CPC H01L 23/3135; H01L 23/49838; H01L 24/32; H01L 23/296; H01L 24/33; H01L 24/48; H01L 24/73; H01L 2224/32013; H01L 2224/32225; H01L 2224/32245; H01L 2224/3303; H01L 2224/33181; H01L 2224/48091; H01L 2224/48175; H01L 2224/73215; H01L 2224/73265; H01L 2924/10253; H01L 2924/10254; H01L 2924/10272; H01L 2924/1033; H01L 2924/12032; H01L 2924/12036; H01L 2924/13055; H01L 2924/13091

(57) ABSTRACT

An object is to provide a technique capable of suppressing a crack that reaches a semiconductor element. A semiconductor device includes a semiconductor element, a lead electrode terminal, a first sealing member, and an intervening member. The lead electrode terminal has an extending portion separated from an upper surface of the semiconductor element, and is bonded to the semiconductor element. The first sealing member seals the lead electrode terminal. The intervening member is provided between an end portion of the extending portion in an extending direction and the semiconductor element. The intervening member has an interface with the first sealing member under the end portion.

### TECHNICAL FIELD

The present disclosure relates to a semiconductor device.

### BACKGROUND ART

As a structure of a case type semiconductor device, a structure in which a semiconductor element and a lead electrode terminal electrically connected to the semiconductor element are sealed with a sealing resin is common. In such a semiconductor device, when a hot-cold cycle occurs due to repetition of operation and non-operation of the semiconductor element, a stress occurs in the sealing resin due to a difference in linear expansion coefficient between the lead electrode terminal and the sealing resin. Due to this stress, a crack that develops from an end portion of the lead electrode terminal and reaches the semiconductor element may occur in the sealing resin.

In order to reduce such a stress, a technique of using a material having a linear expansion coefficient close to a linear expansion coefficient of the lead electrode terminal for the sealing resin, a technique of devising a shape of the lead electrode terminal, and the like have been proposed. For example, Patent Document 1 proposes a technique of using a lead electrode terminal having a special shape in order to reduce a stress of a sealing resin associated with expansion and contraction of a lead electrode terminal.

### PRIOR ART DOCUMENT

### Patent Document

Patent Document 1: Japanese Patent Application Laid-Open No. 2016-082048

### SUMMARY

### Problem to be Solved by the Invention

However, in a case where a temperature difference of the cold-hot cycle is large, a crack that reaches the semiconductor element still occurs, and there is a problem that reliability of the semiconductor device is lowered.

Therefore, the present disclosure has been made in view of the above problem, and an object thereof is to provide a technique capable of suppressing a crack that reaches a semiconductor element.

### Means to Solve the Problem

A semiconductor device according to the present disclosure includes: a semiconductor element; a lead electrode terminal having an extending portion separated from an upper surface of the semiconductor element and bonded to the semiconductor element; a first sealing member that seals the lead electrode terminal; and an intervening member provided between an end portion of the extending portion in an extending direction and the semiconductor element, the intervening member having an interface with the first sealing member under the end portion.

### Effects of the Invention

According to the present disclosure, there is provided an intervening member that is provided between an end portion in an extending direction of a lead electrode terminal and a semiconductor element and has an interface with a first sealing member under the end portion. According to such a configuration, a crack that reaches the semiconductor element can be suppressed.

The objects, features, aspects, and advantages of the present disclosure will become more apparent from the following detailed description and the accompanying drawings.

### BRIEF DESCRIPTION OF DRAWINGS

FIG. 1 is a cross-sectional view showing a configuration of a semiconductor device according to a first embodiment.

FIG. 2 is a cross-sectional view showing a configuration of a related semiconductor device.

FIG. 3 is a cross-sectional view showing a configuration of a part of the related semiconductor device.

FIG. 4 is a cross-sectional view showing a configuration of a part of the semiconductor device according to the first embodiment.

FIG. 5 is a cross-sectional view showing a configuration of a part of a semiconductor device according to a second embodiment.

FIG. 6 is a cross-sectional view showing a configuration of a part of a semiconductor device according to a third embodiment.

FIG. 7 is a top view showing a configuration of a part of the semiconductor device according to the third embodiment.

FIG. 8 is a cross-sectional view showing a configuration of a part of a semiconductor device according to a fourth embodiment.

FIG. 9 is a cross-sectional view showing a configuration of a part of a semiconductor device according to a fifth embodiment.

FIG. 10 is a cross-sectional view showing a configuration of a part of a semiconductor device according to a sixth embodiment.

FIG. 11 is a cross-sectional view showing a configuration of a part of a semiconductor device according to a seventh embodiment.

FIG. 12 is a cross-sectional view showing a configuration of a part of a semiconductor device according to an eighth embodiment.

FIG. 13 is a cross-sectional view showing a configuration of a part of a semiconductor device according to a ninth embodiment.

### DESCRIPTION OF EMBODIMENTS

Hereinafter, embodiments will be described with reference to the accompanying drawings Features described in the following embodiments are illustrative, and all features are not necessarily essential. In addition, in the following description, similar components in a plurality of embodiments are denoted by the same or similar reference signs, and different components will be mainly described. Furthermore, in the following description, specific positions and directions such as “upper”, “lower”, “left”, “right”, “front”, or “back” may not necessarily coincide with actual positions and directions in practice.

### First Embodiment

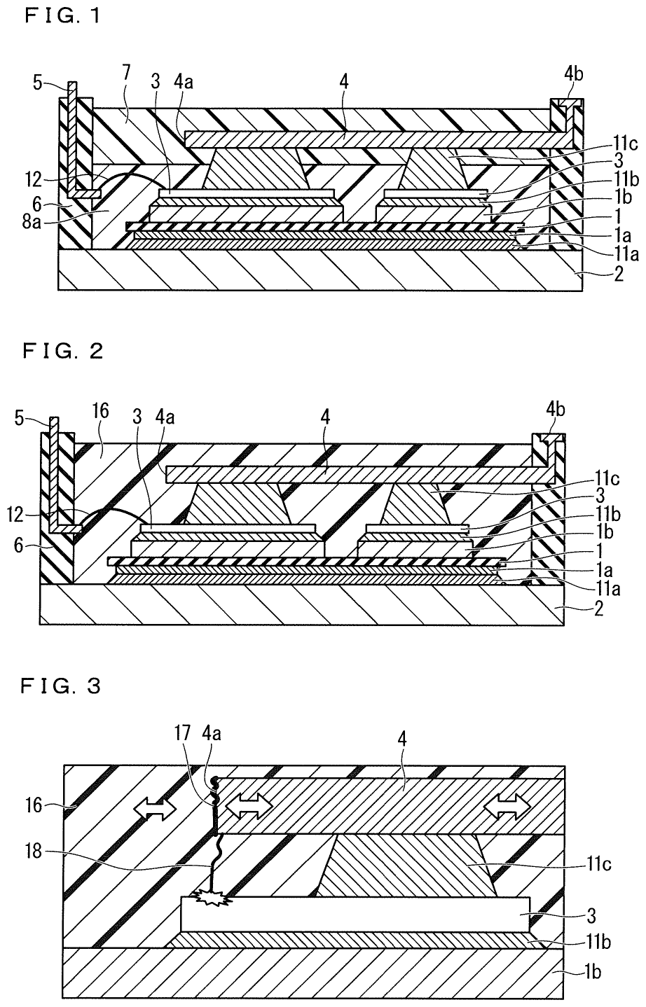

FIG. 1 is a cross-sectional view showing a configuration of a semiconductor device according to the first embodiment. The semiconductor device in FIG. 1 may be an inverter or a converter that controls a motor of an electric car, a train, or the like, or may be a device other than these.

The semiconductor device in FIG. 1 includes an insulating substrate 1, a fin 2, a semiconductor element 3, a lead electrode terminal 4, a signal terminal 5, a case 6, a sealing resin 7 as a first sealing member, and a sealing resin 8a as a second sealing member.

A conductive pattern 1a is provided on a lower surface of the insulating substrate 1, and a conductive pattern 1b is provided on an upper surface of the insulating substrate 1. The fin 2 is bonded to the conductive pattern 1a by a bonding member 11a such as solder and a brazing material.

The semiconductor element 3 is bonded to the conductive pattern 1b by a bonding member 11b such as solder and a brazing material. The semiconductor element 3 includes, for example, a semiconductor switching element such as an insulated gate bipolar transistor (IGBT) and a metal oxide semiconductor field effect transistor (MOSFET), or a diode such as a PN junction diode (PND) and a Schottky barrier diode (SBD). In the first embodiment, a material of the semiconductor element 3 is general silicon (Si), but is not limited thereto as described later. In the first embodiment, a number of the semiconductor elements 3 is two, but may be one or more.

The lead electrode terminal 4 is a plate-like member made of a metal material such as copper, for example, and is bonded to the semiconductor element 3. The lead electrode terminal 4 has an extending portion extending along an upper surface of the semiconductor element 3, and the extending portion is separated from the upper surface of the semiconductor element 3. Note that in the first embodiment, the extending portion of the lead electrode terminal 4 is bonded to the semiconductor element 3, but the present invention is not limited thereto. For example, when the lead electrode terminal 4 has a protruding portion protruding downward, the protruding portion may be bonded to the semiconductor element 3. In the first embodiment, the lead electrode terminal 4 is bonded to the semiconductor element 3 by a bonding member 11c such as solder and a brazing material, but may be, for example, directly bonded to the semiconductor element 3.

The signal terminal 5 is electrically connected to the semiconductor element 3 by a wire 12.

The case 6 is an insert case made of resin or the like, for example, and is provided on the fin 2 to surround a periphery of the semiconductor element 3 and the like. The case 6 fixes the lead electrode terminal 4 in a state where an end portion 4a of the extending portion of the lead electrode terminal 4 in an extending direction and an electrode terminal 4b that is an end portion of the lead electrode terminal 4 are exposed. Similarly, the case 6 fixes the signal terminal 5 in a state where an end portion of the signal terminal connected to the wire 12 and an end portion different from the end portion are exposed.

The sealing resin 7 is provided in an upper portion of a space surrounded by the case 6 to seal the lead electrode terminal 4. The sealing resin 8a is provided in a lower portion of the space surrounded by the case 6 to seal the semiconductor element 3. Note that in the example of FIG. 1, the sealing resin 8a also seals the insulating substrate 1 and the like. Each of the sealing resin 7 and the sealing resin 8a is made of, for example, an epoxy resin or the like.

Here, at least a part of the sealing resin 8a is provided between the end portion 4a of the lead electrode terminal 4 and the semiconductor element 3, and functions as an intervening member having an interface with the sealing resin 7 under the end portion 4a. Such an interface is formed, for example, by separately forming the sealing resin 7 and the sealing resin 8a with the same resin under the same manufacturing conditions. When the sealing resin 7 is formed after the sealing resin 8a is formed once, a linear expansion coefficient of the sealing resin 8a is larger than a linear expansion coefficient of the sealing resin 7, but the linear expansion coefficient of the sealing resin 7 and the linear expansion coefficient of the sealing resin 8a may be the same.

FIG. 2 is a cross-sectional view showing a configuration of a semiconductor device related to the semiconductor device according to the first embodiment (hereinafter, referred to as a “related semiconductor device”). The related semiconductor device includes a sealing resin 16 having no interface under the end portion 4a instead of the sealing resin 7 and the sealing resin 8a.

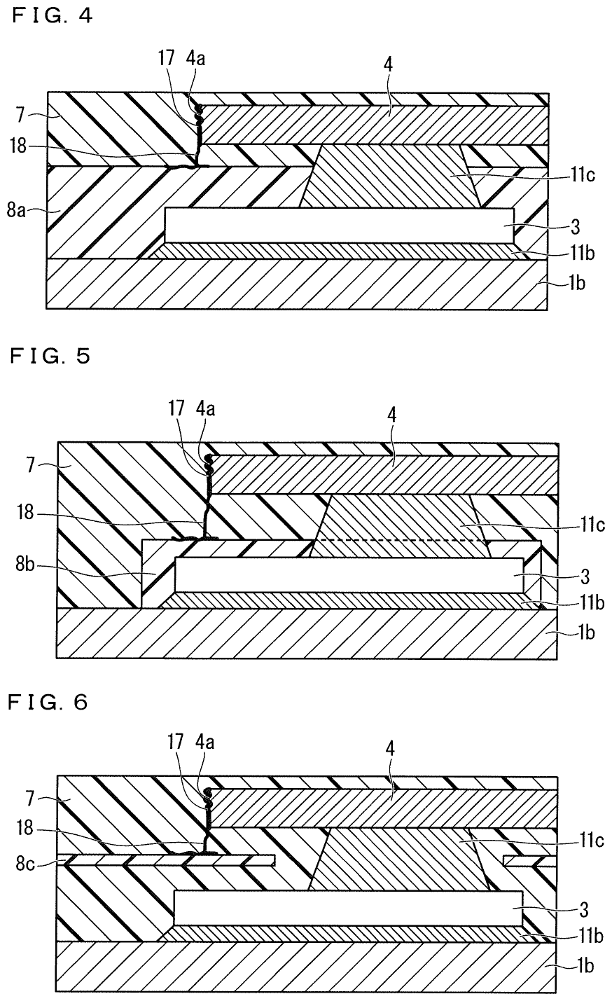

In this related semiconductor device, when a hot-cold cycle occurs due to repetition of operation and non-operation of the semiconductor element 3, a peeling 17 occurs between the end portion 4a and the sealing resin 16 due to a difference in linear expansion coefficient between the lead electrode terminal 4 and the sealing resin 16, as shown in FIG. 3. Furthermore, when the cold-hot cycle further occurs due to the repetition of the operation and non-operation of the semiconductor element 3, a stress concentrates on the sealing resin 16 in contact with the end portion 4a, and a crack 18 that reaches the semiconductor element 3 from the end portion 4a may occur in the sealing resin 16. In this case, there arises a problem that the reliability of the semiconductor device is lowered.

Various techniques for solving such a problem have been proposed. However, in recent years, due to a demand for increasing a maximum working temperature of a semiconductor device, a change in an operating temperature of the semiconductor device or an ambient temperature of the semiconductor device increases, a temperature difference of the cold-hot cycle increases, and the stress generated in the resin increases. For this reason, even when the conventional technique is used, there is a problem that the occurrence of the crack 18, an increase in development speed of the crack 18, and the like occur.

### Summary of First Embodiment

In the first embodiment, the sealing resin 8a is provided between the end portion 4a of the lead electrode terminal 4 and the semiconductor element 3, and functions as an intervening member having an interface with the sealing resin 7 under the end portion 4a. As a result, as shown in FIG. 4, even when the crack 18 that develops from the end portion 4a of the lead electrode terminal 4 to the semiconductor element 3 in a vertical direction occurs in the sealing resin 7, a development direction of the crack 18 changes to an interface direction (that is, a horizontal direction) by the interface between the sealing resin 7 and the sealing resin 8a. Therefore, the crack 18 that reaches the semiconductor element 3 can be suppressed, so that the reliability of the semiconductor device such as a cold-hot cycle resistance can be enhanced.

### First Modification of First Embodiment

In the first embodiment, physical property values of the sealing resin 7 and physical property values of the sealing resin 8a may be different from each other. Note that the physical property values are, for example, a linear expansion coefficient, a mechanical strength, and the like.

When the physical property value is the linear expansion coefficient, a difference between the linear expansion coefficient of the sealing resin 7 and a linear expansion coefficient of the lead electrode terminal 4 may be smaller than a difference between the linear expansion coefficient of the sealing resin 8a and the linear expansion coefficient of the lead electrode terminal 4. That is, the linear expansion coefficient of the sealing resin 7 may be closer to the linear expansion coefficient of the lead electrode terminal 4. According to such a configuration, it is possible to suppress the occurrence of the crack 18 in the sealing resin 7 adjacent to the end portion 4a of the lead electrode terminal 4.

In addition, a difference between the linear expansion coefficient of the sealing resin 8a and a linear expansion coefficient of the insulating substrate 1 may be smaller than a difference between the linear expansion coefficient of the sealing resin 7 and the linear expansion coefficient of the insulating substrate 1. That is, the linear expansion coefficient of the sealing resin 8a may be closer to the linear expansion coefficient of the insulating substrate 1. According to such a configuration, it is possible to suppress deformation of a warp of the semiconductor device due to the cold-hot cycle over time and the occurrence of the crack 18 in the sealing resin 8a adjacent to the insulating substrate 1.

When the physical property value is a mechanical strength, a mechanical strength of the sealing resin 8a may be larger than a mechanical strength of the sealing resin 7. According to such a configuration, it is possible to suppress the occurrence of the crack 18 that reaches the semiconductor element 3 in the sealing resin 8a.

### Second Modification of First Embodiment

A material of the sealing resin 8a in the first embodiment may be a silicone gel. According to such a configuration, even when the crack 18 that develops from the end portion 4a of the lead electrode terminal 4 occurs in the sealing resin 7, the crack 18 that reaches the semiconductor element 3 can be suppressed by the silicone gel. Therefore, the reliability of the semiconductor device such as the cold-hot cycle resistance can be enhanced.

### Second Embodiment

FIG. 5 is a cross-sectional view showing a configuration of a part of a semiconductor device according to a second embodiment. In the second embodiment, the sealing resin 8a described in the first embodiment is a molded resin 8b formed by molding. Note that FIG. 5 shows that, as a trace formed by molding, the molded resin 8b is provided along outer peripheries of the semiconductor element 3 and the bonding member 11b without sealing the insulating substrate 1. A resin formed by molding such as the molded resin 8b is generally a high hardness resin.

### Summary of Second Embodiment

In the second embodiment, the sealing resin 8a is the molded resin 8b. According to such a configuration, similarly to the first embodiment, since the development direction of the crack 18 is changed in the interface direction by an interface between the sealing resin 7 and the molded resin 8b, the crack 18 that reaches the semiconductor element 3 can be suppressed.

Further, since the molded resin 8b is a high hardness resin, the crack 18 that reaches the semiconductor element 3 can be further suppressed. Further, since the molded resin 8b does not seal the insulating substrate 1, the occurrence of the crack 18 in the molded resin 8b due to thermal expansion of the insulating substrate 1 can be suppressed.

Note that the configuration of the second embodiment, and at least any of the configurations of the first embodiment or the first or second modifications described above may be combined.

### Third Embodiment

FIG. 6 is a cross-sectional view showing a part of a configuration of a semiconductor device according to a third embodiment. The configuration of the third embodiment is similar to a configuration in which the sealing resin 8a is replaced with a stress buffer frame 8c in the first embodiment.

The stress buffer frame 8c is a plate-like member made of a resin or the like provided apart from the lead electrode terminal 4 and the semiconductor element 3. In the third embodiment, the stress buffer frame 8c is provided between the end portion 4a of the lead electrode terminal 4 and the semiconductor element 3, and functions as an intervening member having an interface with the sealing resin 7 under the end portion 4a. The sealing resin 7 seals not only the lead electrode terminal 4 but also the semiconductor element 3 and the stress buffer frame 8c.

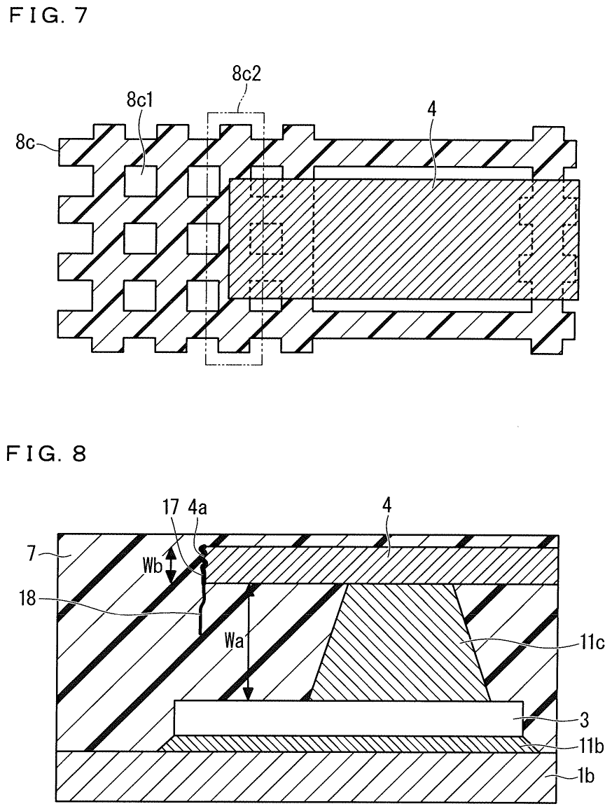

FIG. 7 is a top view showing the lead electrode terminal 4 and the stress buffer frame 8c. The stress buffer frame 8c is preferably provided with a structure through which the sealing resin 7 liquefied at the time of manufacture easily passes, such as a lattice structure having holes 8cl in FIG. 7. According to such a configuration, the sealing resin 7 liquefied at the time of manufacture easily reaches a lower side of the stress buffer frame 8c from an upper side thereof in FIG. 6, and a gap between the sealing resin 7 and the other components can be reduced. In addition, the end portion 4a of the lead electrode terminal 4 is preferably located inside an outline of a line portion 8c2 of the stress buffer frame 8c in plan view. According to such a configuration, it is possible to suppress the occurrence of the crack 18 that reaches the semiconductor element 3.

### Summary of Third Embodiment

In the third embodiment, the molded resin 8b functions as an intervening member similarly to the sealing resin 8a described in the first embodiment. According to such a configuration, similarly to the first embodiment, since the development direction of the crack 18 is changed in the interface direction by the interface between the sealing resin 7 and the stress buffer frame 8c, the crack 18 that reaches the semiconductor element 3 can be suppressed.

Note that the stress buffer frame 8c may be integrated with the case 6. According to such a configuration, it is possible to suppress deformation of a warp of the semiconductor device due to the cold-hot cycle over time. In such a configuration, it is preferable to use a resin having a linear expansion coefficient close to the linear expansion coefficient of the sealing resin 7 for the stress buffer frame 8c.

Note that the configuration of the third embodiment, and at least any of the configurations of the first or second embodiments, or the first or second modifications described above may be combined.

### Fourth Embodiment

FIG. 8 is a cross-sectional view showing a configuration of a part of a semiconductor device according to a fourth embodiment. The semiconductor device according to the fourth embodiment does not include an intervening member such as the sealing resin 8a described in the first embodiment. On the other hand, in the fourth embodiment, a distance Wa between the semiconductor element 3 and the extending portion of the lead electrode terminal 4 is equal to or larger than a thickness Wb of the extending portion, and the sealing resin 7 seals the semiconductor element 3, the lead electrode terminal 4, and the like.

### Summary of Fourth Embodiment

In the fourth preferred, since the distance Wa between the semiconductor element 3 and the extending portion of the lead electrode terminal 4 is relatively large, it is possible to lengthen time until the crack 18 that develops from the end portion 4a of the lead electrode terminal 4 reaches the semiconductor element 3. Therefore, the crack 18 that reaches the semiconductor element 3 can be suppressed, so that the reliability of the semiconductor device such as the cold-hot cycle resistance can be enhanced.

Note that the configuration of the fourth embodiment, and at least any of the configurations of the first to third embodiments, or the first or second modifications described above may be combined.

### Fifth Embodiment

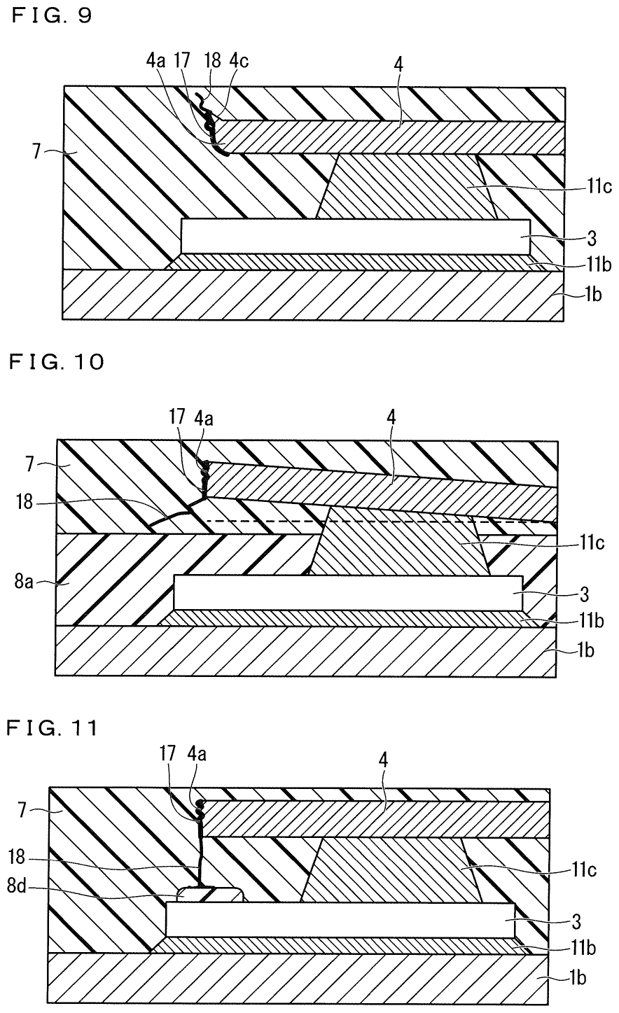

FIG. 9 is a cross-sectional view showing a part of a configuration of a semiconductor device according to a fifth embodiment. The configuration of the fifth embodiment is similar to a configuration in which a protrusion 4c is provided on an upper surface side of the end portion 4a of the lead electrode terminal 4 in the extending direction in the first embodiment. The above-described lead electrode terminal 4 can be formed, for example, by setting punching at the time of forming the lead electrode terminal 4 so as to have a shear droop surface on a side of the semiconductor element 3 and a burr surface on an opposite side of the semiconductor element 3.

### Summary of Fifth Embodiment

In the fifth embodiment, when the crack 18 is formed by the cold-hot cycle, the protrusion 4c can promote the development of the crack 18 on the opposite side of the semiconductor element 3. Therefore, the occurrence of the crack 18 that reaches the semiconductor element 3 can be suppressed, so that the reliability of the semiconductor device such as the cold-hot cycle resistance can be enhanced.

Note that the configuration of the fifth embodiment, and at least any of the configurations of the first to fourth embodiments, or the first or second modifications described above may be combined.

### Sixth Embodiment

FIG. 10 is a cross-sectional view showing a part of a configuration of a semiconductor device according to a sixth embodiment. The configuration of the sixth embodiment is similar to a configuration in which the extending direction of the extending portion of the lead electrode terminal 4 is inclined with respect to the upper surface of the semiconductor element 3 in the first embodiment. That is, an angle between the extending direction of the extending portion of the lead electrode terminal 4 and an in-plane direction of the semiconductor element 3 is larger than 0 degrees.

### Summary of Sixth Embodiment

In the sixth embodiment, since the extending direction of the extending portion of the lead electrode terminal 4 is inclined with respect to the upper surface of the semiconductor element 3, a distance between the semiconductor element 3 and the end portion 4a is large. For example, when the lead electrode terminal 4 is inclined by 5°, the distance between the semiconductor element 3 and the end portion 4a increases by 8.7%. As a result, it is possible to lengthen the time until the crack 18 develops from the end portion 4a of the lead electrode terminal 4 reaches the semiconductor element 3. Therefore, the crack 18 that reaches the semiconductor element 3 can be suppressed, so that the reliability of the semiconductor device such as the cold-hot cycle resistance can be enhanced.

Note that the configuration of the sixth embodiment, and at least any of the configurations of the first to fifth embodiments, or the first or second modifications described above may be combined.

### Seventh Embodiment

FIG. 11 is a cross-sectional view showing a part of a configuration of a semiconductor device according to a seventh embodiment. The configuration of the seventh embodiment is similar to a configuration in which the sealing resin 8a is replaced with a buffer layer 8d in the first embodiment.

The buffer layer 8d is provided on the upper surface of the semiconductor element 3. In the seventh embodiment, the buffer layer 8d is provided between the end portion 4a of the lead electrode terminal 4 and the semiconductor element 3, and functions as an intervening member having an interface with the sealing resin 7 under the end portion 4a. The sealing resin 7 seals not only the lead electrode terminal 4 but also the semiconductor element 3 and the buffer layer 8d.

### Summary of Seventh Embodiment

In the seventh embodiment, the buffer layer 8d functions as an intervening member similarly to the sealing resin 8a described in the first embodiment. According to such a configuration, similarly to the first embodiment, since the development direction of the crack 18 is changed in the interface direction by the interface between the sealing resin 7 and the buffer layer 8d, the crack 18 that reaches the semiconductor element 3 can be suppressed.

Note that the buffer layer 8d is preferably made of a material having a hardness (for example, Vickers hardness) lower than that of the sealing resin 7, such as, for example, a polyimide material. According to such a configuration, since the buffer layer 8d can absorb a stress from the sealing resin 7, the reliability of the semiconductor device such as a cold-hot cycle resistance can be enhanced.

Note that the configuration of the seventh embodiment, and at least any of the configurations of the first to sixth embodiments or the first or second modifications described above may be combined.

### Eighth Embodiment

FIG. 12 is a cross-sectional view showing a part of a configuration of a semiconductor device according to an eighth embodiment. In the configuration of the eighth embodiment, the sealing resin 8a is removed in the configuration of the first embodiment.

On the other hand, in the eighth embodiment, a taper angle of the bonding member 11c that bonds the semiconductor element 3 and the lead electrode terminal 4 is relatively large. As a result, in the eighth embodiment, at least a part of the bonding member 11c is provided between the end portion 4a of the lead electrode terminal 4 and the semiconductor element 3, and functions as an intervening member having an interface with the sealing resin 7 under the end portion 4a. The sealing resin 7 seals not only the lead electrode terminal 4 but also the semiconductor element 3 and the bonding member 11c.

### Summary of Eighth Embodiment

In the eighth embodiment, the bonding member 11c functions as an intervening member similarly to the sealing resin 8a described in the first embodiment. According to such a configuration, the development direction of the crack 18 is changed in the interface direction by the interface between the sealing resin 7 and the bonding member 11c, and the distance until the crack 18 reaches the semiconductor element 3 is increased, so that the crack 18 that reached the semiconductor element 3 can be suppressed.

Note that the configuration of the eighth embodiment, and at least any of the configurations of the first to seventh embodiments or the first or second modifications described above may be combined.

### Ninth Embodiment

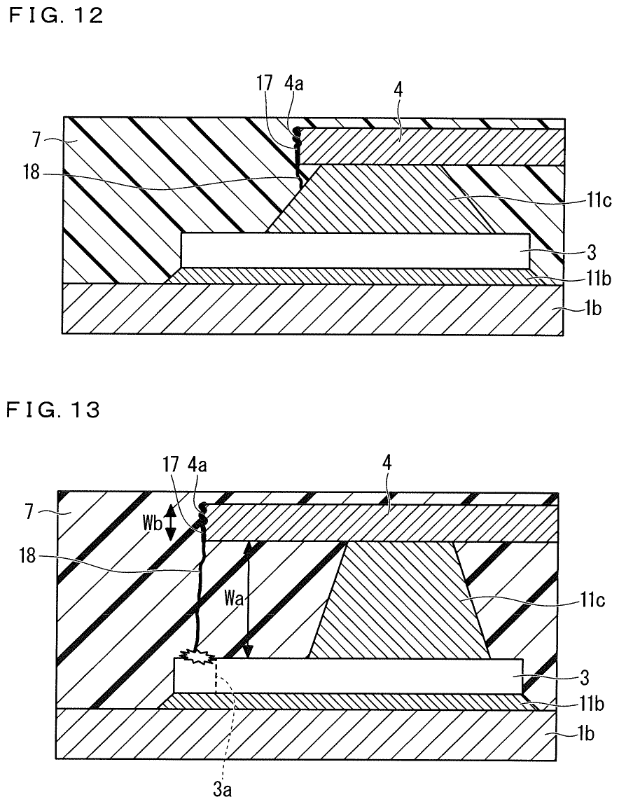

FIG. 13 is a cross-sectional view showing a configuration of a part of a semiconductor device according to a ninth embodiment. The configuration of the ninth embodiment is similar to a configuration in which a region 3a of the semiconductor element 3 immediately below the end portion 4a is a non-conductive region in the fourth embodiment (see FIG. 8). The non-conductive region is a region where the semiconductor element 3 can maintain a normal operation even when the crack 18 reaches the region, and is, for example, a region where a temperature sensor is provided, an insulating region, or the like.

### Summary of Ninth Embodiment

In the ninth embodiment, since the region 3a of the semiconductor element 3 immediately below the end portion 4a is the non-conductive region, even when the crack 18 reaches the semiconductor element 3, the semiconductor element 3 can perform a normal operation. Note that the semiconductor element 3 may be configured to perform an evacuation operation when a defect in the region 3a is detected due to the arrival of the crack 18 or the like. According to such a configuration, it is possible to suppress the occurrence of an unintended sudden stop of the semiconductor element 3 due to a defect in the region 3a.

Note that the configuration of the ninth embodiment, and at least any of the configurations of the first to eighth embodiments or the first or second modifications described above may be combined.

### Modifications of First to Ninth Embodiments

In any of the first to ninth embodiments and the first and second modifications described above, the material of the semiconductor element 3 may be a wide band gap semiconductor. The wide band gap semiconductor is, for example, silicon carbide (SiC), gallium nitride (GaN), diamond, or the like.

Semiconductor element 3 made of the wide band gap semiconductor has a higher hardness (for example, Vickers hardness) than the semiconductor element 3 made of silicon. For example, a hardness of silicon carbide is about 23 GPa, a hardness of silicon is about 10 GPa, and the hardness of the former is about 2.3 times the hardness of the latter. Therefore, by using the wide band gap semiconductor as the material of the semiconductor element 3, a stress resistance to the development of the crack 18 can be enhanced.

Note that the embodiments and the modifications can be freely combined, and the embodiments and the modifications can be appropriately modified or omitted.

The above description is illustrative and not restrictive in all aspects. It is understood that innumerable modifications not illustrated can be envisaged.

### EXPLANATION OF REFERENCE SIGNS

3: semiconductor element
3a: region
4: lead electrode terminal
4a: end portion
4c: protrusion
7, 8a: sealing resin
8b: molded resin
8c: stress buffer frame
8d: buffer layer
11c: bonding member

1. A semiconductor device comprising:
a semiconductor element;
a lead electrode terminal having an extending portion separated from an upper surface of the semiconductor element and bonded to the semiconductor element;
a first sealing member that seals the lead electrode terminal; and
an intervening member provided between an end portion of the extending portion in an extending direction and the semiconductor element, the intervening member having an interface with the first sealing member under the end portion.

2. The semiconductor device according to claim 1, wherein the intervening member includes a second sealing member that seals the semiconductor element.

3. The semiconductor device according to claim 2, wherein a physical property value of the first sealing member and a physical property value of the second sealing member are different from each other.

4. The semiconductor device according to claim 2, wherein a material of the second sealing member includes a silicone gel.

5. The semiconductor device according to claim 2, wherein the second sealing member includes a molded resin.

6. The semiconductor device according to claim 1, wherein
the intervening member includes a stress buffer frame, and
the first sealing member further seals the semiconductor element and the stress buffer frame.

7. The semiconductor device according to claim 1, wherein
the intervening member includes a buffer layer provided on the upper surface of the semiconductor element, and
the first sealing member further seals the semiconductor element and the buffer layer.

8. The semiconductor device according to claim 1, wherein
the intervening member includes a bonding member that bonds the semiconductor element and the lead electrode terminal, and
the first sealing member further seals the semiconductor element and the bonding member.

9. A semiconductor device comprising:
a semiconductor element;
a lead electrode terminal having an extending portion separated from an upper surface of the semiconductor element and bonded to the semiconductor element; and
a sealing member that seals the semiconductor element and the lead electrode terminal, wherein
a distance between the semiconductor element and the extending portion is equal to or more than a thickness of the extending portion.

10. The semiconductor device according to claim 1, wherein a protrusion is provided on an upper surface side of the end portion of the extending portion in the extending direction.

11. The semiconductor device according to claim 1, wherein the extending direction of the extending portion is inclined with respect to the upper surface of the semiconductor element.

12. The semiconductor device according to claim 1, wherein a region of the semiconductor element immediately below the end portion of the extending portion in the extending direction is a non-conductive region.

13. The semiconductor device according to claim 1, wherein a material of the semiconductor element includes a wide band gap semiconductor.
